(19) United States
(12) Patent Application Publication
(10) Pub. No.: US 2026/0190721 A1
(43) Pub. Date: Jul. 2, 2026

(54) DISPLAY DEVICE

(71) Applicant: LG Display Co., Ltd., Seoul (KR)

(72) Inventors: Sohyun Kim, Goyang-si (KR); Junho Lee, Anyang-si (KR)

(73) Assignee: LG Display Co., Ltd., Seoul (KR)

(21) Appl. No.: 19/222,707

(22) Filed: May 29, 2025

(30) Foreign Application Priority Data
Dec. 30, 2024 (KR) 10-2024-0201379

(51) Int. Cl. H10K 59/131; H10K 59/123; H10K 59/124; H10K 59/65

(52) U.S. Cl. CPC H10K 59/1315; H10K 59/123; H10K 59/124; H10K 59/65

(57) ABSTRACT

A display device including a display having a plurality of subpixels on a substrate, in which the display includes an optical area overlapping an electronic optical device disposed below the substrate and includes a display area outside the optical area. The display device also includes a plurality of subpixel circuits disposed in the plurality of subpixels; a plurality of first direct current power lines extending in a first direction in the display area and electrically connected to corresponding first subpixel circuits disposed in the display area among the plurality of subpixel circuits; a plurality of second direct current power lines extending in the first direction in the display area and spaced apart from the first direct current power lines and electrically connected to corresponding second subpixel circuits disposed in the display area among the plurality of subpixel circuits; a first connection line extending in a second direction intersecting the first direction at a boundary between the optical area and the normal area and configured to electrically connect the first direct current power lines, wherein the first connection line is connected to each of the first direct current power lines; a second connection line extending in the second direction at the boundary between the optical area and the display area and spaced apart from the first connection line and configured to electrically connect the plurality of second direct current power lines, wherein the second connection line is connected to each of the second direct current power lines; a third connection line extending in the first direction across the optical area, electrically connected to the first connection line, and electrically connected to corresponding third subpixel circuits disposed in the optical area among the plurality of subpixel circuits; and a fourth connection line extending in the first direction in the optical area and spaced apart from the third connection line, electrically connected to the second connection line, and electrically connected to fourth corresponding subpixel circuits disposed in the optical area among the plurality of subpixel circuits.

### CROSS-REFERENCE TO RELATED APPLICATIONS

This application claims the priority to Korean Patent Application No. 2024-0201379, filed on Dec. 30, 2024, in the Korean Intellectual Property Office, the entire contents of which is hereby incorporated into the present application.

### BACKGROUND

### Field

The present specification relates to a display device, and more particularly, to a display device capable of increasing an open ratio of an optical area in which an electronic optical device is disposed.

### Description of the Related Art

Various studies are conducted to develop a variety of display devices which are thin and lightweight, consume low power, and have improved performance. Examples of display devices include a liquid crystal display device (LCD), a field emission display device (FED), an electrowetting display device (EWD), an organic light-emitting display device (OLED), and the like.

Recently, the multimedia functions of mobile terminals have been improved. For example, a camera or sensor is embedded in a front surface of a mobile terminal display device. However, the camera or sensor disposed on the front surface of the display device restricts a screen design. A notch or punch hole can be provided in the display device to reduce a space occupied by the camera or sensor disposed on the front surface of the display device. However, a screen size is still restricted by the camera or sensor, which makes it difficult to implement a full-screen display.

### SUMMARY

Accordingly, one object to of the present specification is to provide a display device capable of increasing an open ratio of an optical area in which an electronic optical device is disposed.

Another of the present specification is to provide a display device capable of minimizing the occurrence of parasitic capacitance by minimizing the degree to which lines disposed in an optical area overlap one another.

Objects of the present disclosure are not limited to the above-mentioned objects, and other objects, which are not mentioned above, can be clearly understood by those skilled in the art from the following descriptions.

A display device according to one embodiment of the present specification includes a substrate including a display area including an optical area and a normal area and including a subpixels, a plurality of subpixel circuits disposed in the subpixels, a plurality of first direct current power lines and a plurality of second direct current power lines extending in a first direction in the normal area and electrically connected to the subpixel circuit disposed in the normal area among the plurality of subpixel circuits, a first connection line extending in a second direction intersecting the first direction at a boundary between the optical area and the normal area and configured to electrically connect the plurality of first direct current power lines, a second connection line extending in the second direction at the boundary between the optical area and the normal area and configured to electrically connect the plurality of second direct current power lines, a third connection line extending in the first direction in the optical area, electrically connected to the first connection line, and electrically connected to the subpixel circuit disposed in the optical area among the plurality of subpixel circuits, and a fourth connection line extending in the first direction in the optical area, electrically connected to the second connection line, and electrically connected to the subpixel circuit disposed in the optical area among the plurality of subpixel circuits.

A display device according to another embodiment of the present specification includes a substrate including a display area including an optical area and a normal area and including a subpixels, a plurality of subpixel circuits disposed in the subpixels, a plurality of first direct current power lines and a plurality of second direct current power lines extending in a first direction in the normal area and electrically connected to the subpixel circuit disposed in the normal area among the plurality of subpixel circuits, a first connection line extending in a second direction intersecting the first direction at a boundary between the optical area and the normal area and configured to electrically connect the plurality of first direct current power lines, a second connection line extending in the second direction at the boundary between the optical area and the normal area and configured to electrically connect the plurality of second direct current power lines, a third connection line extending in the first direction in the optical area, electrically connected to the first connection line, and electrically connected to the subpixel circuit disposed in the optical area among the plurality of subpixel circuits, and a fourth connection line extending in the first direction in the optical area, electrically connected to the second connection line, and electrically connected to the subpixel circuit disposed in the optical area among the plurality of subpixel circuits, in which the number of first direct current power lines and second direct current power lines disposed in the normal area is larger than the number of third connection line and fourth connection line disposed in the optical area.

According to the display device of the present specification, only a minimum number of direct current power lines can be disposed in the first direction, e.g., the x-axis direction in the optical area in which the electronic optical device is disposed, such that the open ratio of the optical area can be increased, and the performance of the electronic optical device in the optical area can be improved.

That is, the number of direct current power lines extending in the first direction in the optical area can be reduced, such that the overlap between the lines disposed in the optical area is minimized, which reduces the occurrence of parasitic capacitance.

Also, a material with low resistance can be used for the direct current power line in the optical area, such that the RC load can be reduced, and a defect such as crosstalk or Mura can be suppressed.

The effects according to the present disclosure are not limited to the contents exemplified above, and more various effects are included in the present specification.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a block diagram illustrating a display device according to an embodiment of the present specification;

FIG. 2 is a circuit diagram of a subpixel according to the embodiment of the present specification;

FIG. 3 is a waveform diagram illustrating signals applied to a pixel of an organic light-emitting display device according to the embodiment of the present disclosure during one frame;

FIG. 4 is a cross-sectional view taken along line IV-IV′ in FIG. 1;

FIG. 5 is an enlarged top plan view illustrating area A corresponding to an optical area in FIG. 1;

FIG. 6A is an enlarged top plan view of area B in FIG. 5;

FIG. 6B is a cross-sectional view taken along line VI-VI′ in FIG. 6A;

FIG. 7A is an enlarged top plan view of area C in FIG. 5; and

FIG. 7B is a cross-sectional view taken along line VII-VII′ in FIG. 7A.

### DETAILED DESCRIPTION OF THE EMBODIMENT

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies can be omitted to avoid unnecessarily obscuring the subject matter of the present disclosure. The terms such as “including,” “having,” and “consist of” used herein are generally intended to allow other components to be added unless the terms are used with the term “only”. Any references to singular can include plural unless expressly stated otherwise.

Components are interpreted to include an ordinary error range even if not expressly stated. When the position relation between two parts is described using the terms such as “on”, “above”, “below”, and “next”, one or more parts can be positioned between the two parts unless the terms are used with the term “immediately” or “directly”. When an element or layer is disposed “on” another element or layer, another layer or another element can be interposed directly on the other element or therebetween.

Although the terms “first”, “second”, and the like are used for describing various components, these components are not confined by these terms. These terms are merely used for distinguishing one component from the other components. Therefore, a first component to be mentioned below can be a second component in a technical concept of the present disclosure.

Like reference numerals generally denote like elements throughout the specification. A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, various exemplary embodiments of the present disclosure will be described in detail with reference to the accompanying drawings.

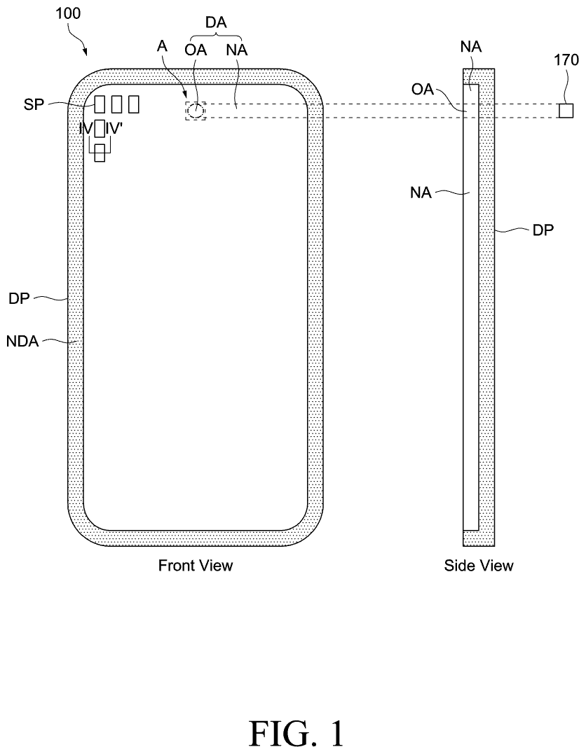

In particular, FIG. 1 is a schematic top plan view of a display device 100 according to an embodiment of the present specification. With reference to FIG. 1, the display device 100 can include a display panel DP configured to display images, and an electronic optical device 170. In particular, the electronic optical device 170 can include a light-receiving device, such as a camera or sensor, that receives light. Further, FIG. 1 illustrates one optical area OA and one electronic optical device 170, but two or more optical areas OA and two or more electronic optical devices 170 can be provided. Also, the optical area OA can be disposed in other areas beside the top center area shown in FIG. 1. For example, two optical area OAs and two corresponding camera or sensors can be disposed behind the two optical areas. The two optical areas OAs can be disposed on left and right sides of the top portion of the display device 100 shown in FIG. 1.

In addition, the display panel DP displays images to a user and includes a display element configured to display images, a driving element configured to operate and drive the display element, and lines configured to transmit various types of signals to the display element and the driving element. Different display elements can be defined depending on the types of display panels DP. For example, when the display panel DP is an organic light-emitting display panel, the display element can be an organic light-emitting element including an anode, an organic layer, and a cathode. Also, when the display panel DP is a liquid crystal display panel, the display element can be a liquid crystal display element.

Hereinafter, it is assumed that the display panel DP is the organic light-emitting display panel. However, the display panel DP is not limited to the organic light-emitting display panel. As shown in FIG. 1, the display panel DP can include a display area DA and a non-display area NDA. In particular, the display area DA is an area of the display panel DP in which images are displayed.

Also, the display area DA can include a plurality of subpixels constituting a plurality of pixels, and a circuit configured to operate the subpixels. In more detail, the subpixel is a minimum unit that constitute the display area DA. In addition, the display element can be disposed in each of the subpixels. The subpixels can thus constitute the pixel. For example, the subpixels can each include the light-emitting element including the anode, the organic layer, and the cathode. In addition, the circuit configured to operate the subpixels can include driving elements, lines, and the like. For example, the circuit can include a thin-film transistor, a storage capacitor, a gate line, a data line, and the like.

Further, the non-display area NDA does not display an image. The non-display area NDA can also be bent, such that the non-display area NDA is not visible from a front surface and also be covered by a casing. The non-display area NDA is also called a bezel area.

In addition, FIG. 1 illustrates that the non-display area NDA surrounds the display area DA having a quadrangular shape. However, the shapes and arrangements of the display area DA and the non-display area NDA are not limited to the example illustrated in FIG. 1. That is, the display area DA and the non-display area NDA can be suitable for the design of an electronic device equipped with the display device 100. Other shapes of the display area DA include a pentagonal shape, a hexagonal shape, a circular shape, an elliptical shape, or the like.

Various lines and circuits for operating the organic light-emitting element in the display area DA are also disposed in the non-display area NDA. For example, the non-display area NDA can include link lines for transmitting signals to the subpixels and the circuit in the display area DA. The non-display area NDA can also include gate-in-panel (GIP) lines or drive ICs such as gate driver ICs and data driver ICs. However, the present specification is not limited thereto.

With reference to FIG. 1, the display area DA can include a normal area NA and the optical area OA. In particular, the optical area OA overlaps the electronic optical device 170. FIG. 1 illustrates the optical area OA has a circular shape. However, the shape of the optical area OA according to the embodiment of the present specification is not limited thereto.

In FIG. 1, the electronic optical device 170 is an electronic component positioned at a lower side (a side opposite to a visual surface) of the display panel DP. Thus, the light can enter the front surface (visual surface) of the display panel DP, pass through the display panel DP, and then propagate to the electronic optical device 170 positioned at the lower side (the side opposite to the visual surface) of the display panel DP.

The electronic optical device 170 receives light having passed through the display panel DP and performs a predetermined function in response to the received light. For example, the electronic optical device 170 can include one of or both a camera and a proximity sensor.

As described above, the electronic optical device 170 receives the light. In addition, the electronic optical device 170 can be positioned at the lower side of the display panel DP. That is, the electronic optical device 170 can be positioned at the side opposite to the visual surface of the display panel DP. The electronic optical device 170 is thus not exposed to the front surface of the display device 100. Therefore, the user does not visually recognize the electronic optical device 170 when the user looks at the front surface of the display device 100.

For example, the camera positioned at the lower side of the display panel DP can be a front surface camera configured to capture an image of an object disposed forward of the camera. The camera can include a camera lens. The optical area OA includes both an image display structure and a light transmission structure. That is, because the optical area OA is a partial area of the display area DA, the subpixels for displaying images are disposed in the optical area OA. The optical area OA thus has the light transmission structure for transmitting light to the electronic optical device 170.

For example, the electronic optical device 170 can be a camera or a detection sensor, such as a proximity sensor or an illuminance sensor. Also, the detection sensor can be an infrared sensor that detects infrared rays. When the electronic optical device 170 is a camera, the camera can be positioned at the rear side (lower side) of the display panel DP. In addition, the camera can be the front surface camera configured to capture an image of an object disposed forward of the display panel DP. Therefore, the user can capture an image by using the camera, which is not visible from the visual surface, while looking at the visual surface of the display panel DP.

In addition, the normal area NA and the optical area OA included in the display area DA display images. However, the normal area NA does not include the light transmission structure, and the optical area OA includes the light transmission structure.

Therefore, the optical area OA includes a transmittance at a predetermined level or higher. Further, the normal area NA may not have optical transmittance or has a low transmittance at less than the predetermined level. For example, the optical area OA and the normal area NA can be different in resolution, subpixel arrangement structure, number of subpixels per unit area, electrode structure, line structure, electrode arrangement structure, line arrangement structure, or the like.

In addition, the number of subpixels per unit area in the optical area OA can be smaller than the number of subpixels per unit area in the normal area NA. That is, the resolution in the optical area OA can be lower than the resolution in the normal area NA. In this instance, the number of subpixels per unit area can be a criterion for measuring the resolution and can also be referred to as PPI (pixels per inch) meaning the number of pixels within 1 inch.

In the display device 100 according to the embodiment of the present specification, when the electronic optical device 170, which is hidden at the lower side of the display panel DP without being exposed to the outside, is a camera, the display device 100 can be a display to which an under-display IR (UDIR) sensor technology is applied. According to this configuration, a notch or camera hole for exposing a camera need not be formed in the display panel DP, such that an area of the display area DA is not decreased. Therefore, because the notch or camera hole for exposing the camera need not be formed in the display panel DP, a size of a bezel area can decrease, and a design constraint can be eliminated, such that a degree of freedom can increase.

Further, even though the electronic optical device 170 is positioned to be hidden at the rear side of the display panel DP, the electronic optical device 170 uses received light light and performs a predetermined function. In addition, even though the electronic optical device 170 is positioned to be hidden at the rear side of the display panel DP and positioned to overlap the display area DA, images are displayed in the optical area OA that overlaps the electronic optical device 170 in the display area DA.

Therefore, the display device 100 according to the embodiment of the present specification can have a structure capable of improving the transmittance of the optical area OA that overlaps the electronic optical device 170.

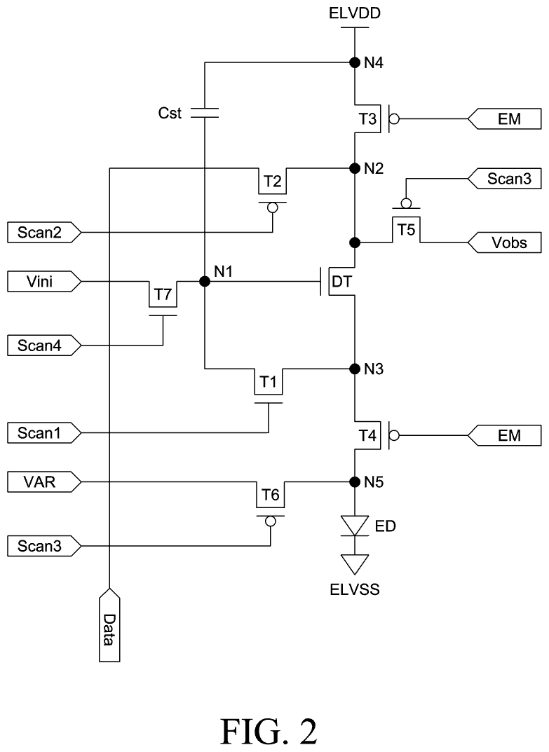

Next, FIG. 2 is a circuit diagram of the subpixel according to the embodiment of the present specification. FIG. 2 exemplarily illustrates the pixel circuit. However, the pixel circuit is not limited as long as the pixel circuit has a structure capable of controlling light emission of a light-emitting element ED by applying a light emission signal EM. For example, the pixel circuit can include an additional scan signal, a switching thin-film transistor connected to the additional scan signal. An additional initialization voltage can also be applied to the switching thin-film transistor and connection relationships between switching elements and connection positions of capacitors can be variously set.

With reference to FIG. 2, the subpixels SP can each include the pixel circuit having a driving transistor DT, and the light-emitting element ED connected to the pixel circuit. For example, the subpixels SP can include a red subpixel configured to emit red light, a green subpixel configured to emit green light, and a blue subpixel configured to emit blue light or include a white subpixel configured to emit white light, a red subpixel, a green subpixel, and a blue subpixel. The subpixel SP can also have one or more different light-emitting areas depending on luminous properties.

In addition, the pixel circuit can operate the light-emitting element ED by controlling a drive current flowing in the light-emitting element ED. As shown, the pixel circuit can include the driving transistor DT, first to seventh transistors T1, T2, T3, T4, T5, T6, and T7, and a capacitor Cst. In particular, the transistors DT, T1, T2, T3, T4, T5, T6, and T7 can each include a first electrode, a second electrode, and a gate electrode. One of the first and second electrodes can be a source electrode, and the other of the first and second electrodes can be a drain electrode.

Further, the transistors DT, T1, T2, T3, T4, T5, T6, and T7 can each be a P-type thin-film transistor or an N-type thin-film transistor. In the embodiment in FIG. 2, the driving transistor DT, the first transistor T1, and the seventh transistor T7 are each configured as an N-type thin-film transistor, and the remaining transistors T2, T3, T4, T5, and T6 are each configured as a P-type thin-film transistor. However, the present specification is not limited thereto. That is, all or some of the transistors DT, T1, T2, T3, T4, T5, T6, and T7 can be the P-type thin-film transistors or the N-type thin-film transistors. In addition, the N-type thin-film transistor can be an oxide thin-film transistor, and the P-type thin-film transistor can be a polycrystalline silicon thin-film transistor.

Hereinafter, an example will be described in which the driving transistor DT, the first transistor T1, and the seventh transistor T7 are each an N-type thin-film transistor, and the remaining transistors T2, T3, T4, T5, and T6 are each a P-type thin-film transistor. Therefore, the driving transistor DT, the first transistor T1, and the seventh transistor T7 are turned on by receiving high voltages, and the remaining transistors T2, T3, T4, T5, and T6 are turned on by receiving low voltages.

In addition, the first transistor T1, which constitutes the pixel circuit, can serve as a compensation transistor, the second transistor T2 can serve as a data supply transistor, the third transistor T3 and the fourth transistor T4 can serve as light emission control transistors, the fifth transistor T5 can serve as a bias transistor, and the sixth transistor T6 and the seventh transistor T7 can serve as initialization transistors.

Further, the light-emitting element ED can include an anode and a cathode. As shown, the anode of the light-emitting element ED can be connected to a fifth node N5, and the cathode can be connected to a low-potential power voltage ELVSS. The driving transistor DT can also include a first electrode connected to a second node N2, a second electrode connected to a third node N3, and a gate electrode connected to a first node N1. The driving transistor DT can provide a drive current to the light-emitting element ED on the basis of a voltage of the first node N1 (or a data voltage stored in the capacitor Cst to be described below).

As shown in FIG. 2, the first transistor T1 can include a first electrode connected to the first node N1, a second electrode connected to the third node N3, and a gate electrode configured to receive a first scan signal Scan1. The first transistor T1 can thus be turned on in response to the first scan signal Scan1 and connected between the first node N1 and the third node N3 by means of a diode, such that the first transistor T1 can sample a threshold voltage Vth of the driving transistor DT. The first transistor T1 can also be a compensation transistor.

In addition, the capacitor Cst can be connected or formed between the first node N1 and a fourth node N4 and can store or maintain a provided high-potential power voltage ELVDD. Also, the second transistor T2 can include a first electrode configured to receive a data voltage Data, a second electrode connected to the second node N2, and a gate electrode configured to receive a second scan signal Scan2. Therefore, the second transistor T2 can be turned on in response to the second scan signal Scan2 and transmit the data voltage Data to the second node N2. The second transistor T2 can also be a data supply transistor.

Further, as shown, the third transistor T3 and the fourth transistor T4 can be connected between the high-potential power voltage ELVDD and the light-emitting element ED and define a current flow path through which the drive current, which is generated by the driving transistor DT, flows. The third transistor T3 can also include a first electrode connected to a fourth node N4 and configured to receive the high-potential power voltage ELVDD, a second electrode connected to the second node N2, and a gate electrode configured to receive a light emission control signal EM.

In addition, the fourth transistor T4 can include a first electrode connected to the third node N3, a second electrode connected to the fifth node N5, and a gate electrode configured to receive the light emission control signal EM. The third transistor T3 and the fourth transistor T4 can thus be turned on in response to the light emission control signal EM. In this instance, the drive current can be provided to the light-emitting element ED, and the light-emitting element ED can emit light with luminance corresponding to the drive current.

Further, the fifth transistor T5 can include a first electrode configured to receive a bias voltage Vobs, a second electrode connected to the second node N2, and a gate electrode configured to receive a third scan signal Scan3. The fifth transistor T5 can also be a bias transistor. In addition, the sixth transistor T6 can include a first electrode configured to receive a first initialization voltage Var, a second electrode connected to the fifth node N5, and a gate electrode configured to receive the third scan signal Scan3.

Before the light-emitting element ED emits light or after the light-emitting element ED emits light, the sixth transistor T6 can be turned on in response to the third scan signal Scan3 and initialize the anode of the light-emitting element ED by using the first initialization voltage Var. Also, the light-emitting element ED can have a parasitic capacitor formed between the anode and the cathode. Further, the parasitic capacitor is charged while the light-emitting element ED emits light, such that the anode of the light-emitting element ED can have a particular voltage. Therefore, it is possible to initialize a charge quantity accumulated in the light-emitting element ED by applying the first initialization voltage Var to the anode of the light-emitting element ED through the sixth transistor T6.

In addition, the seventh transistor T7 can include a first electrode configured to receive a second initialization voltage Vini, a second electrode connected to the first node N1, and a gate electrode configured to receive a fourth scan signal Scan4. Thus, the seventh transistor T7 can be turned on in response to the fourth scan signal Scan4 and initialize the gate electrode of the driving transistor DT by using the second initialization voltage Vini. Unnecessary electric charges may remain on the gate electrode of the driving transistor DT because of the high-potential power voltage ELVDD stored in the capacitor Cst. Therefore, it is possible to initialize the residual charge quantity by applying the second initialization voltage Vini to the gate electrode of the driving transistor DT through the seventh transistor T7.

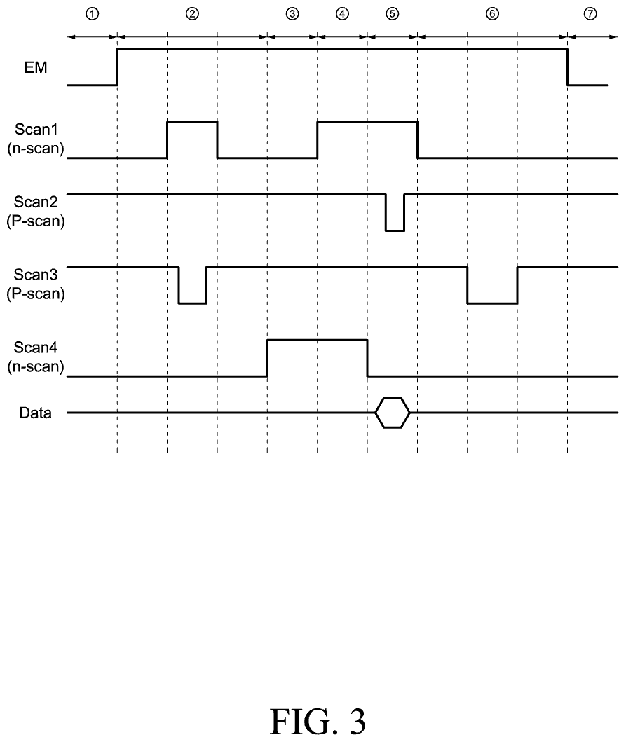

Next, FIG. 3 is a waveform diagram illustrating signals applied to a pixel of an organic light-emitting display device according to the embodiment of the present disclosure during one frame. As shown, in a first section \textcircled{1}, all the first to seventh transistors T1, T2, T3, T4, T5, T6, and T7 and the driving transistor DT can be turned off.

Also, in a second section \textcircled{2}, the first transistor T1 can be turned on in response to the first scan signal Scan1, the first transistor T1 can be turned on, and then the fifth transistor T5 and the sixth transistor T6 can be turned on in response to the third scan signal Scan3. Thereafter, in the second section \textcircled{2}, the fifth transistor T5 and the sixth transistor T6 can be turned off in response to the third scan signal Scan3, and then the first transistor T1 can be turned off in response to the first scan signal Scan1.

In addition, the seventh transistor T7 can be turned on in a third section \textcircled{3} in response to the fourth scan signal Scan4 and kept turned on in a fourth section \textcircled{4}. In the fourth section \textcircled{4}, the first transistor T1 can be turned on in response to the first scan signal Scan1. Thereafter, in the fourth section \textcircled{4}, the seventh transistor T7 can be turned off in response to the fourth scan signal Scan4. In the fourth section \textcircled{4}, the turned-on the first transistor T1 can be maintained in a fifth section \textcircled{5}.

In the fifth section \textcircled{5}, the second transistor T2 can be turned on in response to the second scan signal Scan2 and transmit the data voltage Data to the second node N2. In addition, based on the data voltage Data, the drive current can be transmitted to the driving transistor DT and the fourth transistor T4 to turn on the light-emitting element ED.

Thereafter, in the fifth section \textcircled{5}, the second transistor T2 can be turned off in response to the second scan signal Scan2. Also, the light-emitting element ED can be turned off as the second transistor T2 is turned off. Next, the first transistor T1 can be turned off in response to the first scan signal Scan1. In addition, in a sixth section \textcircled{6}, the fifth transistor T5 and the sixth transistor T6 can be turned on in response to the third scan signal Scan3. Thereafter, the fifth transistor T5 and the sixth transistor T6 can be turned off in the sixth section \textcircled{6} in response to the third scan signal Scan3 and kept turned off in a seventh section \textcircled{7}.

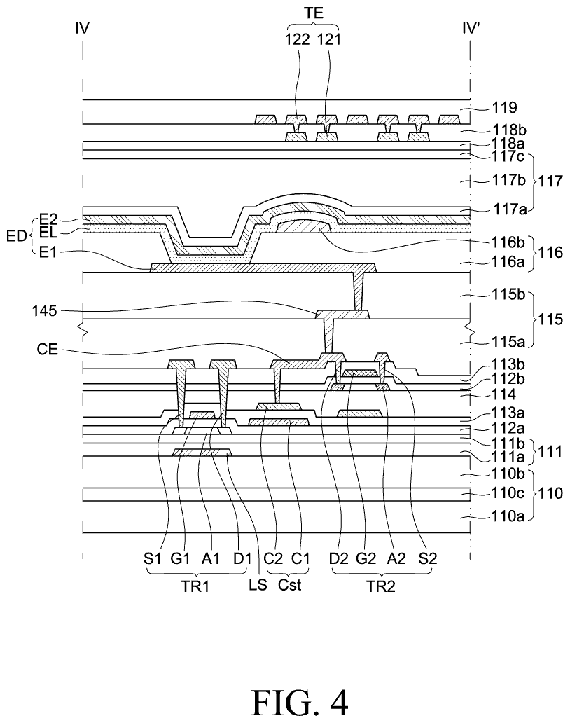

Hereinafter, a cross-sectional structure of the display device 100 will be described in more detail with reference to FIG. 4.

In particular, FIG. 4 is a cross-sectional view taken along line IV-IV′ in FIG. 1. With reference to FIGS. 1 and 4, the display panel DP of the display device 100 according to the embodiment of the present specification can include a substrate 110, a first buffer layer 111, a first thin-film transistor TR1, a second thin-film transistor TR2, a first gate insulation layer 112a, a first interlayer insulation layer 113a, a second buffer layer 114, a second gate insulation layer 112b, a second interlayer insulation layer 113b, a connection electrode CE, a first planarization layer 115a, a second planarization layer 115b, an auxiliary electrode 145, a bank 116a, a spacer 116b, an anode E1, an organic layer EL, a cathode E2, an encapsulation part 117, a touch electrode TE, a first organic layer 119a, and a second organic layer 119b.

Also, the substrate 110 serves to support and protect constituent elements of the display device 100 that are disposed above the substrate 110. The substrate 110 is a component for supporting various constituent elements included in the display device 100 and can be made of an insulating material. In addition, the substrate 110 can include a first substrate 110a, a second substrate 110b, and an interlayer insulation film 110c. As shown, the interlayer insulation film 110c can be disposed between the first substrate 110a and the second substrate 110b. As described above, the substrate 110 is configured by the first substrate 110a, the second substrate 110b, and the interlayer insulation film 110c, which can suppress moisture permeation. For example, the first substrate 110a and the second substrate 110b can each be a polyimide (PI) substrate, and the interlayer insulation film 110c can be configured as a single layer made of silicon nitride (SiNx) or silicon oxide (SiOx) or a multilayer including the above-mentioned layers.

As shown in FIG. 4, a light-blocking layer LS can be disposed on the substrate 110, and the first buffer layer 111 can be disposed on the substrate 110 while covering the light-blocking layer LS. Specifically, a multi-buffer layer 111a can be disposed on the substrate 110 while covering the light-blocking layer LS, and an active buffer layer 111b can be disposed on the multi-buffer layer 111a.

In addition, the multi-buffer layer 111a can delay diffusion of moisture or oxygen having permeated into the substrate 110 and include at least any one of silicon nitride (SiNx) and silicon oxide (SiOx). Further, the active buffer layer 111b can protect a first active layer A1 and suppress various types of defects introduced from the substrate 110. For example, the active buffer layer 111b can include at least any one of a-Si, silicon nitride (SiNx), and silicon oxide (SiOx).

As shown, the first thin-film transistor TR1 can be disposed on the first buffer layer 111. In particular, the first thin-film transistor TR1 can include the first active layer A1, a first gate electrode G1, a first source electrode S1, and a first drain electrode D1. In this instance, in accordance with design of a pixel circuit, the first source electrode D1 can be a first drain electrode, and the first drain electrode D1 can be a first source electrode.

In addition, the first active layer A1 can be disposed on the first buffer layer 111 so as to overlap the light-blocking layer LS. In particular, the first active layer A1 can include amorphous silicon or polysilicon (polycrystalline silicon). For example, the first active layer A1 can include low-temperature polysilicon (LTPS). Also, because a polysilicon material has high mobility (100 cm²/Vs or more), low energy power consumption, and excellent reliability, the polysilicon material can be applied to gate drivers and/or multiplexers (MUX) for driving elements for operating thin-film transistors for display elements. LAO, the polysilicon material can be applied to an active layer A1 of the thin-film driving transistor. However, the present specification is not limited thereto. For example, the polysilicon material can also be applied to an active layer A2 of the switching thin-film transistor in accordance with the properties of the display device 100. In addition, the first active layer A1 can be formed by depositing an amorphous silicon (a-Si) material on the first buffer layer 111, forming polysilicon by performing a dehydration process and a crystallization process, and then patterning the polysilicon. In this instance, the first active layer A1 can include a first channel area in which a channel is formed when the first thin-film transistor TR1 operates, and a first source area and a first drain area disposed at two opposite sides of the first channel area. The first source area means a portion of the first active layer A1 connected to the first source electrode S1, and the first drain area means a portion of the first active layer A1 connected to the first drain electrode D1. For example, the first source area and the first drain area can be configured by doping the first active layer A1 with ions (impurities). In addition, the first source area and the first drain area can be formed by doping the polysilicon material with ions. The first channel area can be a portion in which the polysilicon material remains without being subjected to the ion doping.

In addition, the first gate insulation layer 112a can be disposed on the first active layer A1. In particular, the first gate insulation layer 112a can be configured as a single layer made of silicon nitride (SiNx) or silicon oxide (SiOx) or a multilayer including the above-mentioned layers. Also, the first gate insulation layer 112a can have contact holes through which the first source electrode S1 and the first drain electrode D1 of the first thin-film transistor TR1 are respectively connected to the first source area and the first drain area of the first active layer A1 of the first thin-film transistor TR1.

In addition, the first gate electrode G1 of the first thin-film transistor TR1 and a first capacitor electrode C1 of a storage capacitor Cst can be disposed on the first gate insulation layer 112a. In this instance, the first gate electrode G1, a gate metal GM, and the first capacitor electrode C1 can each be configured as a single layer or multilayer made of any one of molybdenum (Mo), copper (Cu), titanium (Ti), aluminum (Al), chromium (Cr), gold (Au), nickel (Ni), and neodymium (Nd) or an alloy thereof. Also, the first gate electrode G1 can be formed on the first gate insulation layer 112a so as to overlap the first channel area of the first active layer A1 of the first thin-film transistor TR1.

The first capacitor electrode C1 can also be excluded based on the operating properties of the display device 100 and the structure, type, and the like of the thin-film transistor. In addition, the first gate electrode G1 and the first capacitor electrode C1 can be formed by the same process. Further, the first gate electrode G1 and the first capacitor electrode C1 can be made of the same material and formed on the same layer.

As shown, the first interlayer insulation layer 113a can be disposed above the first gate insulation layer 112a, the first gate electrode G1, and the first capacitor electrode C1. In particular, the first interlayer insulation layer 113a can be configured as a single layer made of silicon nitride (SiNx) or silicon oxide (SiOx) or a multilayer including the above-mentioned layers. Further, the first interlayer insulation layer 113a can have a contact hole through which the first source area and the first drain area of the first active layer A1 of the first thin-film transistor TR1 are exposed.

As shown in in FIG. 4, a second capacitor electrode C2 of the storage capacitor Cst can be disposed on the first interlayer insulation layer 113a. In particular, the second capacitor electrode C2 can be configured as a single layer or multilayer made of any one of molybdenum (Mo), copper (Cu), titanium (Ti), aluminum (Al), chromium (Cr), gold (Au), nickel (Ni), neodymium (Nd), and an alloy thereof. The second capacitor electrode C2 can also be formed on the first interlayer insulation layer 113a so as to overlap the first capacitor electrode C1. In addition, the second capacitor electrode C2 can be made of the same material as the first capacitor electrode C1. The second capacitor electrode C2 can be excluded on the basis of the operating properties of the display device 100 and the structure, type, and the like of the thin-film transistor.

Further, the second buffer layer 114 can be disposed on the first interlayer insulation layer 113a and the second capacitor electrode C2. In particular, the second buffer layer 114 can be configured as a single layer made of silicon nitride (SiNx) or silicon oxide (SiOx) or a multilayer including the above-mentioned layers. Also, the second buffer layer 114 can have a contact hole through which the first source area and the first drain area of the first active layer A1 of the first thin-film transistor TR1 are exposed. In addition, the second buffer layer 114 can have a contact hole through which the second capacitor electrode C2 of the storage capacitor Cst is exposed.

Also, the second buffer layer 114 can be configured as a multilayer. However, the present specification is not limited thereto. A second active layer A2 of the second thin-film transistor TR2 can also be disposed on the second buffer layer 114. In this instance, the second thin-film transistor TR2 can include the second active layer A2, the second gate insulation layer 112b, a second gate electrode G2, a second source electrode S2, and a second drain electrode D2. In accordance with design of the pixel circuit, the second source electrode S2 can be a drain electrode, and the second drain electrode D2 can be a source electrode.

In addition, the second active layer A2 can include a second channel area in which a channel is formed when the second thin-film transistor TR2 operates, and a second source area and a second drain area disposed at two opposite sides of the second channel area. The second source area can be a portion of the second active layer A2 connected to the second source electrode S2, and the second drain area can mean a portion of the second active layer A2 connected to the second drain electrode D2.

Further, the second active layer A2 can be made of an oxide semiconductor having a larger band gap than a silicon material and having a low off-current because electrons cannot pass through the band gap in an OFF state. Therefore, the thin-film transistor including the active layer made of the oxide semiconductor can be suitable for a switching thin-film transistor that maintains the short ON time and the long OFF time. However, the present specification is not limited thereto. The oxide semiconductor can also be applied to the thin-film driving transistor in accordance with the properties of the display device 100. Further, because the oxide semiconductor material has a low off-current and can decrease a magnitude of an auxiliary capacity, the oxide semiconductor material is suitable for a high-resolution display element. For example, the second active layer A2 can be made of a metal oxide, for example, various metal oxides such as indium-gallium-zinc oxide (IGZO). In this instance, the description has been made on the assumption that the second active layer A2 of the second thin-film transistor TR2 is made of IGZO among various metal oxides. However, the present specification is not limited thereto. The second active layer A2 of the second thin-film transistor TR2 can also be made of another metal oxide, such as indium-zinc oxide (IZO), indium-gallium-tin oxide (IGTO), or indium-gallium oxide (IGO), instead of IGZO.

In addition, the second active layer A2 can be formed by depositing a metal oxide on the second buffer layer 114, performing a heat treatment process for stabilization, and then patterning the metal oxide. The second gate insulation layer 112b can also be disposed on the entire substrate 110 including the second active layer A2. For example, the second gate insulation layer 112b can be configured as a single layer made of silicon nitride (SiNx) or silicon oxide (SiOx) or a multilayer including the above-mentioned layers.

Further, the second gate electrode G2 can be disposed on the second gate insulation layer 112b. In particular, the second gate electrode G2 can be configured as a single layer or multilayer made of any one of molybdenum (Mo), copper (Cu), titanium (Ti), aluminum (Al), chromium (Cr), gold (Au), nickel (Ni), neodymium (Nd), and an alloy thereof.

For example, the second gate electrode G2 is formed by forming a metallic material on the second gate insulation layer 112b, forming a photoresist pattern on the metallic material, and then wet-etching the metallic material by using the photoresist pattern as a mask. A material, which selectively etches molybdenum (Mo), copper (Cu), titanium (Ti), aluminum (Al), chromium (Cr), gold (Au), nickel (Ni), and neodymium (Nd), or an alloy thereof, which constitutes the metallic material and does not etch the insulating material, can be used as a wet etching liquid for etching the metallic material.

In addition, the second interlayer insulation layer 113b can be disposed on the second gate insulation layer 112b and the second gate electrode G2. In particular, the second interlayer insulation layer 113b can have a contact hole through which the first active layer A1 of the first thin-film transistor TR1 and the second active layer A2 of the second thin-film transistor TR2 are exposed. For example, the second interlayer insulation layer 113b can have a contact hole through which the first source area and the first drain area of the first active layer A1 of the first thin-film transistor TR1 are exposed. Also, the second interlayer insulation layer 113b can have a contact hole through which the second source area and the second drain area of the second active layer A2 of the second thin-film transistor TR2 are exposed.

In addition, the second interlayer insulation layer 113b can be configured as a single layer made of silicon nitride (SiNx) or silicon oxide (SiOx) or a multilayer including the above-mentioned layers. The connection electrode CE, the first source electrode S1 and the second drain electrode D1 of the first thin-film transistor TR1, and the second source electrode S2 and the second drain electrode D2 of the second thin-film transistor TR2 can also be disposed on the second interlayer insulation layer 113b.

Also, the connection electrode CE can be electrically connected to the second drain electrode D2 of the second thin-film transistor TR2. Further, the connection electrode CE can be electrically connected to the second capacitor electrode C2 of the storage capacitor Cst through contact holes formed in the second buffer layer 114 and the second interlayer insulation layer 113b. That is, the connection electrode CE can serve to electrically connect the second capacitor electrode C2 of the storage capacitor Cst and the second drain electrode D2 of the second thin-film transistor TR2.

In this instance, the first source electrode S1 and the first drain electrode D1 of the first thin-film transistor TR1 can be connected to the first active layer A1 of the first thin-film transistor TR1 through contact holes formed in the first gate insulation layer 112a, the first interlayer insulation layer 113a, the second buffer layer 114, and the second interlayer insulation layer 113b. The second source electrode S2 and the second drain electrode D2 of the second thin-film transistor TR2 can also be connected to the second active layer A2 through a contact hole formed in the second interlayer insulation layer 112b.

In addition, the connection electrode CE, the first source electrode S1 and the first drain electrode D1 of the first thin-film transistor TR1, and the second source electrode S2 and the second drain electrode D2 of the second thin-film transistor TR2 can be formed by the same process and made of the same material. For example, the connection electrode CE, the first source electrode S1 and the first drain electrode D1 of the first thin-film transistor TR1, and the second source electrode S2 and the second drain electrode D2 of the second thin-film transistor TR2 can each configured as a single layer or multilayer made of any one of molybdenum (Mo), copper (Cu), titanium (Ti), aluminum (Al), chromium (Cr), gold (Au), nickel (Ni), and neodymium (Nd) or an alloy thereof. Also, the connection electrode CE, the first source electrode S1 and the first drain electrode D1 of the first thin-film transistor TR1, and the second source electrode S2 and the second drain electrode D2 of the second thin-film transistor TR2 can each have a three-layer structure including titanium (Ti)/aluminum (Al)/titanium (Ti). However, the present specification is not limited thereto.

In addition, the connection electrode CE can be integrally connected to the second drain electrode D2 of the second thin-film transistor TR2. However, the present specification is not limited thereto. The first planarization layer 115a can also be disposed above the connection electrode CE, the first source electrode S1 and the first drain electrode D1 of the first thin-film transistor TR1, the second source electrode S2 and the second drain electrode D2 of the second thin-film transistor TR2, and the second interlayer insulation layer 113b.

Further, the first planarization layer 115a can be an organic layer for planarizing and protecting an upper portion of the first thin-film transistor TR1 and an upper portion of the second thin-film transistor TR2. For example, the first planarization layer 115a can be made of an organic material such as acrylic resin, epoxy resin, phenolic resin, polyamide resin, and polyimide resin.

In addition, the auxiliary electrode 145 can be disposed on the first planarization layer 115a. In particular, the auxiliary electrode 145 can be connected to the second drain electrode D2 of the second thin-film transistor TR2 through a contact hole of the first planarization layer 115a. The auxiliary electrode 145 can also serve to electrically connect the second thin-film transistor TR2 and the anode E1. Further, the auxiliary electrode 145 can be configured as a single layer or multilayer made of any one of molybdenum (Mo), copper (Cu), titanium (Ti), aluminum (Al), chromium (Cr), gold (Au), nickel (Ni), neodymium (Nd), and an alloy thereof. The auxiliary electrode 145 can be made of the same material as the second source electrode S2 and the second drain electrode D2 of the second thin-film transistor TR2.

In addition, the second planarization layer 115b can be disposed above the auxiliary electrode 145 and the first planarization layer 115a. For example, the second planarization layer 115b can be made of an organic material such as acrylic resin, epoxy resin, phenolic resin, polyamide resin, and polyimide resin.

Further, the light-emitting element ED can be disposed on the second planarization layer 115b, and the anode E1 can be disposed on the second planarization layer 115b. In this instance, the anode E1 can be electrically connected to the auxiliary electrode 145 through a contact hole provided in the second planarization layer 115b. The anode E1 can be made of a metallic material.

When the display device 100 is a top-emission type display device in which light emitted from the light-emitting element ED propagates toward an upper side of the substrate SUB on which the light-emitting element ED is disposed, the anode E1 can further include a transparent conductive layer and a reflective layer disposed on the transparent conductive layer. For example, the transparent conductive layer can be made of transparent conductive oxide such as ITO or IZO. Also, the reflective layer can be made of silver (Ag), aluminum (Al), gold (Au), molybdenum (Mo), tungsten (W), chromium (Cr), or an alloy thereof.

In addition, the bank 116a can be disposed to cover the anode E1. A portion of the bank 116a, which corresponds to the light-emitting area of the subpixel, can be opened. A part of the anode E1 can be exposed through the opened portion (hereinafter, referred to as an open area) of the bank 116a. In this instance, the bank 116a can be made of an inorganic insulating material such as silicon nitride (SiNx) or silicon oxide (SiOx), or an organic insulating material such as benzocyclobutene-based resin, acrylic resin, or imide-based resin. However, the present specification is not limited thereto. The spacer 116b can be further disposed on the bank 116a.

In addition, the organic layer EL can be disposed in the open area of the bank 116a and an area at the periphery of the open area. Therefore, the organic layer EL can be disposed on the anode E1 exposed through the open area of the bank 116a. The organic layer EL can include a plurality of organic films. For example, the organic layer EL serves to emit light. The organic layer EL can include a hole injection layer (HIL), a hole transport layer (HTL), a light-emitting layer, an electron transport layer (ETL), and an electron injection layer (EIL). However, some components can be excluded depending on the structure or properties of the display device. In this case, an electroluminescent layer and an inorganic light-emitting layer can be applied as the organic layer EL.

Further, the hole injection layer is disposed on the anode E1 and serves to facilitate the injection of the positive holes. Also, the hole transport layer is disposed on the hole injection layer and serves to smoothly transmit the positive holes to the light-emitting layer. In addition, light-emitting layer is disposed on the hole transport layer and can be made of a material capable of emitting light with a particular color, thereby emitting the light with the particular color. For example, a phosphorescent material or a fluorescent material can be used as the light-emitting material.

Also, the electron injection layer can further be disposed on the electron transport layer. In particular, the electron injection layer is an organic layer that facilitates the injection of electrons from the cathode E2. The electron injection layer can also be excluded depending on the structure and properties of the display device.

An electron blocking layer for blocking a flow of electrons or a hole blocking layer for blocking a flow of positive holes can be further disposed at a position adjacent to the organic layer EL. Therefore, it is possible to inhibit the electron from moving from the light-emitting layer and passing through the adjacent hole transport layer when the electrons are injected into the light-emitting layer or inhibit the positive hole from moving from the light-emitting layer and passing through the adjacent electron transport layer when the positive holes are injected into the light-emitting layer, thereby improving luminous efficiency.

In addition, the cathode E2 can be disposed on the organic layer EL and serves to supply electrons to the organic layer EL. Therefore, the cathode E2 can be made of a metallic material such as magnesium (Mg), a silver-magnesium alloy, or the like that is an electrically conductive material having a low work function. However, the present specification is not limited thereto. For example, when the display device 100 is a top-emission type display device, the cathode E2 can include transparent conductive oxide such as indium tin oxide (ITO), indium zinc oxide (IZO), indium-tin-zinc oxide (ITZO), zinc oxide (ZnO), and tin oxide (TO). The light-emitting element ED can be formed by the anode E1, the organic layer EL, and the cathode E2.

As shown in FIG. 4, an encapsulation layer 117 can be positioned on the light-emitting element ED and can have a single-layer structure or a multilayer structure. For example, the encapsulation layer 117 can include a first encapsulation layer 117a, a second encapsulation layer 117b, and a third encapsulation layer 117c.

In this instance, the first encapsulation layer 117a and the third encapsulation layer 117c can each be made of an inorganic film, and the second encapsulation layer 117b can be made of an organic film. Among the first encapsulation layer 117a, the second encapsulation layer 117b, and the third encapsulation layer 117c, the second encapsulation layer 117b can be thickest and serve as a planarization layer.

Also, the first encapsulation layer 117a can be disposed on the cathode E2 and closest to the light-emitting element ED. In particular, the first encapsulation layer 117a can be made of an inorganic insulating material that can be deposited at a low temperature. For example, the first encapsulation layer 117a can be made of silicon nitride (SiNx), silicon oxide (SiOx), silicon oxynitride (SiON), aluminum oxide (Al₂O₃), or the like. Because the first encapsulation layer 117a is deposited in a low-temperature ambience, it is possible to suppress damage to the organic layer EL made of an organic material vulnerable to a high-temperature ambience during a deposition process.

In addition, the second encapsulation layer 117b can have a smaller area than the first encapsulation layer 117a. Also, the second encapsulation layer 117b can be formed to expose two opposite ends of the first encapsulation layer 117a. The second encapsulation layer 117b can also serve as a buffer for mitigating stress between the layers caused when the display device 100 is bent. The second encapsulation layer 117b can also improve the planarization performance. For example, the second encapsulation layer 117b can be made of an organic insulating material such as acrylic resin, epoxy resin, polyimide, polyethylene, or silicon oxycarbon (SiOC). The second encapsulation layer 117b can also be formed in an inkjet manner. However, the present specification is not limited thereto.

In addition, the third encapsulation layer 117c can be formed above the substrate 110 having the second encapsulation layer 117b to cover a top surface and a side surface of each of the second encapsulation layer 117b and the first encapsulation layer 117a. In this instance, the third encapsulation layer 117c can minimize or block the permeation of outside moisture or oxygen into the first encapsulation layer 117a and the second encapsulation layer 117b. For example, the third encapsulation layer 117c can be made of an inorganic insulating material such as silicon nitride (SiNx), silicon oxide (SiOx), silicon oxynitride (SiON), or aluminum oxide (Al₂O₃).

A touch detection part can also be disposed on the third encapsulation layer 117c. Specifically, the touch detection part can include a touch buffer layer 118a disposed on the third encapsulation layer 117c, a plurality of bridge electrodes 121 disposed on the touch buffer layer 118a, a touch interlayer insulation layer 118b disposed on the plurality of bridge electrodes 121, a plurality of touch electrodes 122 disposed on the touch interlayer insulation layer 118b, and an organic material layer 119 disposed to cover the plurality of touch electrodes 122. The touch buffer layer 118a can thus inhibit outside moisture, foreign substances, or a liquid chemical such as a developer or an etching liquid, which is used during a process of manufacturing the touch electrodes TE formed on the touch buffer layer 118a, from permeating into the light-emitting element ED.

In order to suppress damage to the organic layer EL including an organic material vulnerable to a high temperature, the touch buffer layer 118a can be made of an organic insulating material that can be formed at a predetermined low temperature (e.g., 100° C. or less) and have low permittivity of 1 to 3. For example, the touch buffer layer 118a can be made of an acrylic-based, epoxy-based, or siloxane-based material. The touch buffer layer 118a can also be formed to extend to the non-display area NA or the optical area OA as well as the display area AA. Further, the plurality of bridge electrodes 121 are disposed on the touch buffer layer 118a. In particular, the bridge electrodes 121 are disposed in the display area AA and electrically connect the plurality of touch electrodes 122 on the touch interlayer insulation layer 118b.

In this instance, the contact hole can be formed through the touch interlayer insulation layer 118b and the bridge electrodes 121 are disposed below the touch interlayer insulation layer 118b, and upper portions of the bridge electrodes 121 are partially exposed by the contact holes. For example, the bridge electrodes 121 can each be configured as a single layer or multilayer made of any one of molybdenum (Mo), copper (Cu), titanium (Ti), aluminum (Al), chromium (Cr), gold (Au), nickel (Ni), and neodymium (Nd) or an alloy thereof. However, the present specification is not limited thereto. For example, the bridge electrodes 121 can each have a three-layer structure made of titanium (Ti), aluminum (Al), and titanium (Ti).

Further, the touch interlayer insulation layer 118b can be disposed on the touch buffer layer 118a to cover the plurality of bridge electrodes 121 and insulate the plurality of bridge electrodes 121 and the plurality of touch electrodes 122. The touch interlayer insulation layer 118b can be formed to extend to the non-display area NA or the optical area OA as well as the display area AA. For example, the touch interlayer insulation layer 118b can be configured as a single layer or multilayer made of silicon nitride (SiNx) or silicon oxide (SiOx). However, the present specification is not limited thereto.

In addition, the touch electrodes 122 are disposed on the touch interlayer insulation layer 118b and are connected in a first direction to define a electrode columns and connected in a row direction by the bridge electrodes 121 to define a electrode rows. For example, the touch electrodes 122 can each be configured as a single layer or multilayer made of any one of molybdenum (Mo), copper (Cu), titanium (Ti), aluminum (Al), chromium (Cr), gold (Au), nickel (Ni), and neodymium (Nd) or an alloy thereof. However, the present specification is not limited thereto. For example, the touch electrodes 122 can each have a three-layer structure made of titanium (Ti), aluminum (Al), and titanium (Ti).

In addition, the organic material layer 119 can be disposed to cover the touch electrodes TE. For example, the organic material layer 119 can be made of an organic material such as acrylic resin, epoxy resin, phenolic resin, polyamide resin, and polyimide resin. The organic material layer 119 can also suppress a level difference of the constituent elements of the display panel DP disposed below the organic material layer 119, thereby improving the visibility of the display device. In addition, the organic material layer 119 can be disposed on an uppermost layer of the display panel DP, thereby suppressing the occurrence of a crack in the uppermost layer of the display panel DP caused by an external force. For example, the organic material layer 119 can also be referred to as a touch planarization layer 119. Also, the organic material layer 119 can be configured as a single layer or multilayer.

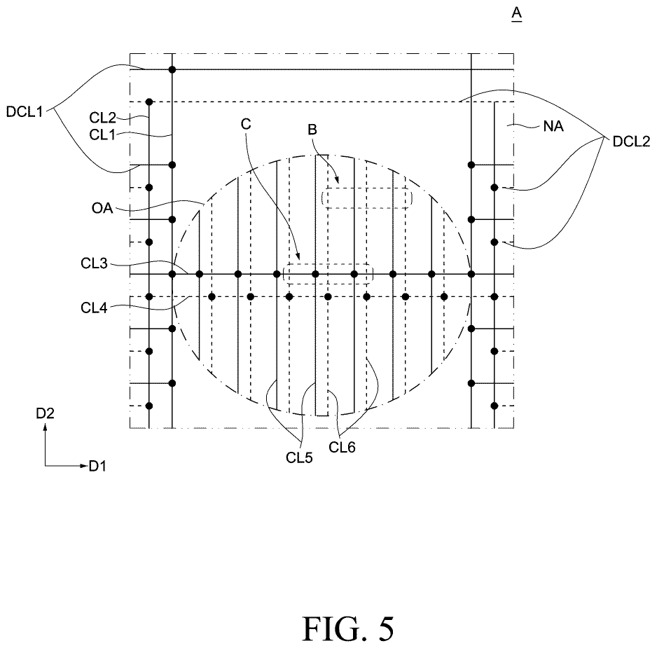

Hereinafter, the optical area OA will be described in more detail with reference to FIGS. 5 to 7.

In particular, FIG. 5 is an enlarged top plan view illustrating area A corresponding to an optical area in FIG. 3. For convenience of description, FIG. 5 illustrates only a plurality of first direct current power lines DCL1 and a plurality of second direct current power lines DCL2 extending from the normal area NA to the optical area OA, a first connection line CL1 and a second connection line CL2 respectively and electrically connected to the first direct current power lines DCL1 and the second direct current power lines DCL2, a third connection line CL3 and a fourth connection line CL4 respectively and electrically connected to the first connection line CL1 and the second connection line CL2, and fifth connection lines CL5 and sixth connection lines CL6 respectively branching off from the third connection line CL3 and the fourth connection line CL4.

With reference to FIG. 5, in the normal area NA, the first direct current power lines DCL1 and the second direct current power lines DCL2 can extend in a first direction D1. For convenience of description, in the normal area NA, the first direct current power lines DCL1 and the second direct current power lines DCL2 can be further disposed to surround the optical area OA. In this instance, the first direct current power lines DCL1 and the second direct current power lines DCL2 disposed in the normal area NA can be spaced apart from the fifth connection line CL5 and the sixth connection line CL6 disposed in the optical area OA to be described below.

The first direct current power lines DCL1 and the second direct current power lines DCL2 are configured to apply direct current (DC) power. For example, the first direct current power lines DCL1 and the second direct current power lines DCL2 can be disposed on the same layer and made of the same material.

In addition, the first direct current power lines DCL1 and the second direct current power lines DCL2 can apply the direct current power to red subpixels SPR, green subpixels SPG, and blue subpixels SPR disposed in the normal area NA. For example, the first direct current power lines DCL1 can apply the direct current power to the red subpixels SPR and blue subpixels SPB, and the second direct current power lines DCL2 can apply the direct current power to the green subpixels SPG. The direct current power can be the first initialization voltage Var, the second initialization voltage Vini, or the bias voltage Vobs. For example, the first direct current power lines DCL1 can each be any one of a first initialization voltage Var line, a second initialization voltage Vini line, and a bias voltage Vobs line configured to apply the first initialization voltage Var, the second initialization voltage Vini, and the bias voltage Vobs to the red subpixel SPR and the blue subpixel SPB. The second direct current power lines DCL2 can each be any one of the first initialization voltage Var line, the second initialization voltage Vini line, and the bias voltage Vobs line configured to apply the first initialization voltage Var, the second initialization voltage Vini, and the bias voltage Vobs to the green subpixel SPG.

For example, the first direct current power lines DCL1 and the second direct current power lines DCL2 can be electrically connected to the subpixels disposed in the normal area NA. The first connection line CL1 and the second connection line CL2 are disposed at a boundary between the optical area OA and the normal area NA in a second direction intersecting the first direction D1.

In addition,, the first connection line CL1 is electrically connected to the first direct current power lines DCL1. Therefore, a signal transmitted through the first direct current power line DCL1 can be transmitted to the first connection line CL1 at the boundary between the display area AA and the optical area OA. That is, the first connection line CL1 can be electrically connected to the first direct current power lines DCL1 and transmit the direct current power applied to the red subpixel SPR and the blue subpixel SPB.

Further, the second connection line CL2 is electrically connected to the second direct current power lines DCL2. Therefore, a signal transmitted through the second direct current power line DCL2 can be transmitted to the second connection line CL2 at the boundary between the display area AA and the optical area OA. That is, the second connection line CL2 can be electrically connected to the second direct current power lines DCL2 and transmit the direct current power applied to the green subpixel SPG.

Also, the third connection line CL3 extending in the first direction D1 in the optical area OA can be electrically connected to the first connection line CL1 disposed in the normal area NA. In addition, the third connection line CL3 can be electrically connected to the subpixel disposed in the optical area OA. For example, the first direct current power lines DCL1 can be grouped into one line by the first connection line CL1, and the first connection line CL1 can be electrically connected to the third connection line CL3 and applied to the optical area OA. Therefore, it is possible to reduce the number of lines extending in the first direction D1 in the optical area OA and configured to apply first direct current power.

In addition, the direct current power, which is applied to the red subpixel SPR and the blue subpixel SPB disposed in the optical area OA, can be transmitted to the third connection line CL3 through the first connection line CL1. For example, the third connection line CL3 and the first direct current power lines DCL1 can be disposed on the same layer and made of the same material.

The fourth connection line CL4 extending in the first direction D1 in the optical area OA can be electrically connected to the second connection line CL2 disposed in the normal area NA. In addition, the fourth connection line CL4 can be electrically connected to the subpixel disposed in the optical area OA. For example, the second direct current power lines DCL2 can be grouped into one line by the second connection line CL2, and the second connection line CL2 can be electrically connected to the fourth connection line CL4 and applied to the optical area OA. Therefore, it is possible to reduce the number of lines extending in the first direction D1 in the optical area OA and configured to apply second direct current power.

The direct current power, which is applied to the green subpixel SPG disposed in the optical area OA, can also be transmitted to the fourth connection line CL4 through the second connection line CL2. For example, the fourth connection line CL4 and the second direct current power lines DCL2 can be disposed on the same layer and made of the same material. For example, the third connection line CL3 and the fourth connection line CL4 can extend while traversing a center of the optical area OA.

Also, the first direct current power lines DCL1, the second direct current power lines DCL2, the third connection line CL3, and the fourth connection line CL4 can be positioned on the same layer as the first source electrode S1, the first drain electrode D1, the second source electrode S2, the second drain electrode D2, and the connection electrode CE. For example, the first source electrode S1, the first drain electrode D1, the second source electrode S2, the second drain electrode D2, and the connection electrode CE can be lower in resistance than the first gate electrode G1, the second capacitor electrode C2, or the second gate electrode G2. Therefore, a material with relatively low resistance can be used for the third connection line CL3 and the fourth connection line CL4, such that an RC load can be reduced, and a delay of a direct current power signal applied to the subpixel in the optical area OA can be minimized.

In addition, in the optical area OA, the fifth connection lines CL5 branching off from the third connection line CL3 in the second direction D2 can be disposed, and the sixth connection lines CL6 branching off from the fourth connection line CL4 in the second direction D2 can be disposed.

In order to easily apply the first direct current power and the second direct current power to the subpixels disposed in the optical area OA, the third connection line CL3 and the fourth connection line CL4 can branch in the second direction D2. For example, the fifth connection line CL5 can be electrically connected to the first direct current power lines DCL1 through the first connection line CL1 and third connection line CL5 and transmit the direct current power applied to the red subpixel SPR and the blue subpixel SPB disposed in the optical area OA. Also, the sixth connection line CL6 can be electrically connected to the second direct current power lines DCL2 through the second connection line CL2 and the fourth connection line CL4 and transmit the direct current power applied to the green subpixel SPG disposed in the optical area OA.

In addition, the fifth connection line CL5 and the sixth connection line CL6 can be disposed on the same layer and made of the same material as the first connection line CL1 and the second connection line CL2. For example, the first connection line CL1, the second connection line CL2, the fifth connection line CL5, and the sixth connection line CL6 can be positioned on the same layer as the auxiliary electrode 145. Further, the auxiliary electrode 145 can be lower in resistance than the first gate electrode G1, the second capacitor electrode C2, or the second gate electrode G2. Therefore, a material with relatively low resistance can be used for the fifth connection line CL5 and the sixth connection line CL6, such that an RC load can be reduced, and a delay of the direct current power signal applied to the subpixel in the optical area OA can be minimized. In addition, it is possible to suppress in advance a defect such as crosstalk or Mura by reducing the RC load in the optical area OA.

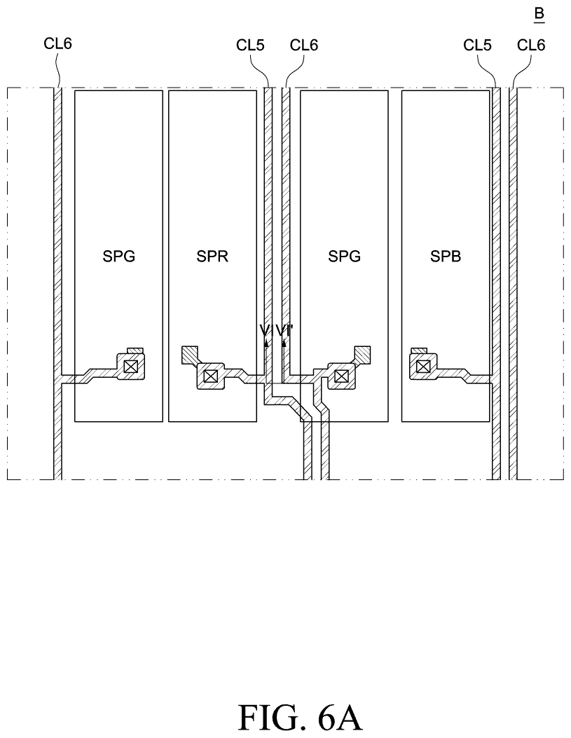

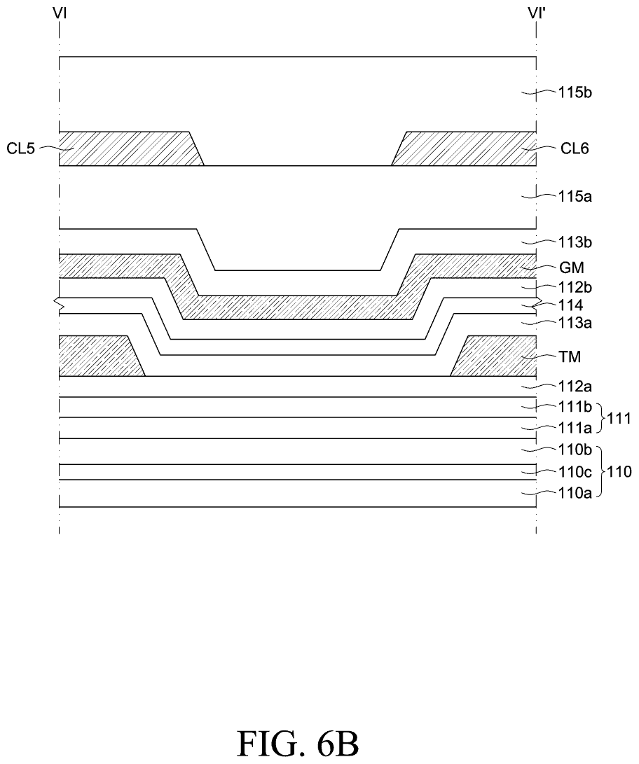

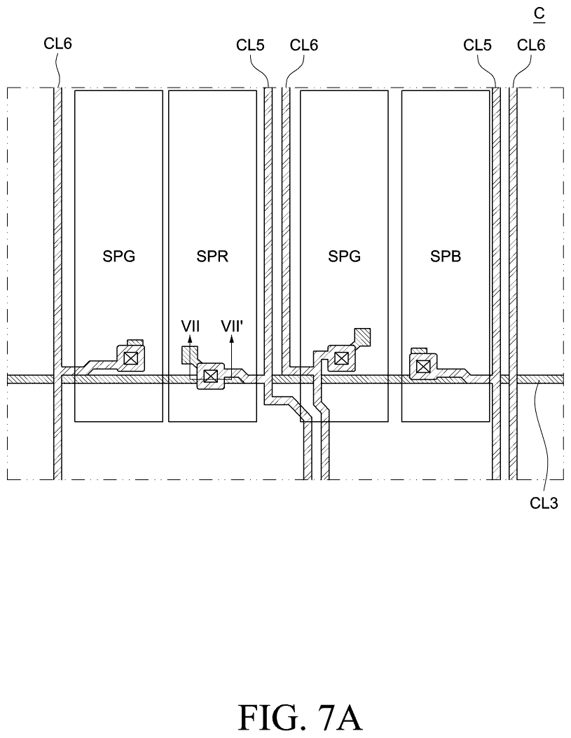

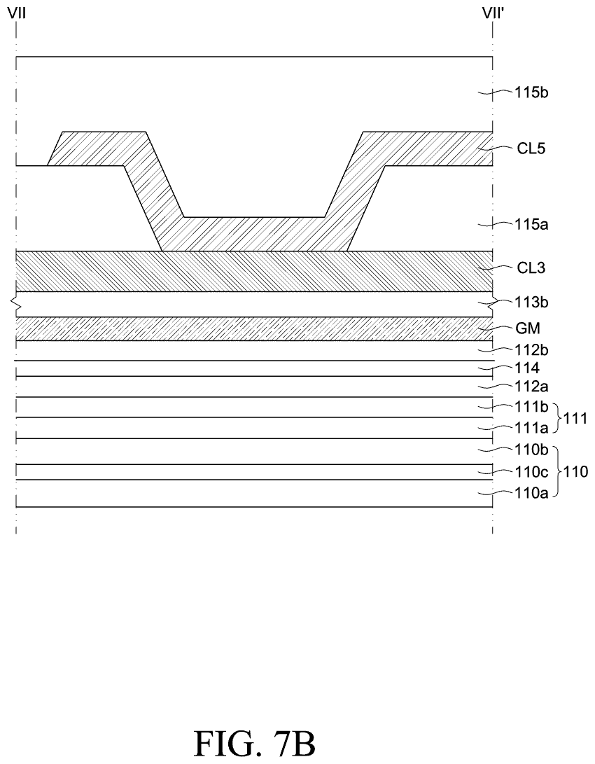

Next, FIG. 6A is an enlarged top plan view of area B in FIG. 5, FIG. 6B is a cross-sectional view taken along line VI-VI′ in FIG. 6A, FIG. 7A is an enlarged top plan view of area C in FIG. 5 and FIG. 7B is a cross-sectional view taken along line VII-VII′ in FIG. 7A. For convenience of description, FIGS. 6A and 6B illustrate only the fifth connection line CL5 and the sixth connection line CL6 extending in the second direction and an area electrically connected to the fifth connection line CL5 and the sixth connection line CL6. For convenience of description, FIGS. 7A and 7B illustrate only the third connection line CL3 extending in the first direction, the fifth connection line CL5 electrically connected to the third connection line CL3 and extending in the second direction intersecting the third connection line CL3, the sixth connection line CL6 extending in the second direction intersecting the third connection line CL3, and an area electrically connected to the fifth connection line CL5 and the sixth connection line CL6.

With reference to FIGS. 5, 6A, and 6B, in an area that is not a center of the optical area OA, only the fifth connection line CL5 branching off from the third connection line CL3 and the sixth connection line CL6 branching off from the fourth connection line CL4 can extend and apply the first direct current power and the second direct current power to the red subpixel SPR, the green subpixel SPG, and the blue subpixel SPB.

With reference to FIGS. 4, 6A, and 6B together, in the optical area OA, a metal pattern TM can be disposed on the first gate insulation layer 112a and positioned on the same layer as the first gate electrode G1. For example, the metal pattern TM can float.

In addition, the first interlayer insulation layer 113a, the second buffer layer 114, and the second gate insulation layer 112b can be disposed to cover the metal pattern TM. In the optical area OA, a gate pattern GM can be disposed on the gate insulation layer 112b and positioned on the same layer as the second gate electrode G2.

Further, the second interlayer insulation layer 113b and the first planarization layer 115a can be disposed to cover the gate pattern GM. The sixth connection line CL6 can be disposed on the first planarization layer 115a and positioned on the same layer as the auxiliary electrode 145.

With reference to FIGS. 5, 6A, and 6B together, in an area that is not the center of the optical area OA, only the fifth connection line CL5 electrically connected to the third connection line CL3 and the sixth connection line CL6 electrically connected to the fourth connection line CL4 can be present, and the fifth connection line CL5 and the sixth connection line CL6 can apply the direct current power to the subpixels disposed in the optical area OA. For example, the fifth connection line CL5 can apply the direct current power to the red subpixel SPR and the blue subpixel SPB disposed in the optical area OA. For example, the sixth connection line CL6 can apply the direct current power to the green subpixel SPG disposed in the optical area OA.

In addition, the connection between the third connection line CL3 and the fifth connection line CL5 and the connection between the fourth connection line CL4 and the sixth connection line CL6 will be described below with reference to FIGS. 7A and 7B.

Meanwhile, with reference to FIGS. 5, 7A, and 7B, the third connection line CL3 and the fourth connection line CL4 can be disposed at the center of the optical area OA and extend, the fifth connection line CL5 and the sixth connection line CL6 can respectively branch off from the third connection line CL3 and the fourth connection line CL4. For example, the third connection line CL3 can be electrically connected to the first direct current power lines DCL1 through the first connection line CL1 at the center of the optical area OA, and the third connection line CL5 can apply the first direct current power to the red subpixel SPR and the blue subpixel SPB disposed at the center of the optical area OA. For example, the fourth connection line CL4 can be electrically connected to the second direct current power lines DCL2 through the second connection line CL2 at the center of the optical area OA, and the fourth connection line CL4 can apply the second direct current power to the green subpixel SPG disposed in the optical area OA.

In addition, with reference to FIGS. 4, 5, 7A, and 7B together, the fifth connection line CL5 and the sixth connection line CL6 can respectively branch off from the third connection line CL3 and the fourth connection line CL4 at the center of the optical area OA. Specifically, at the center of the optical area OA, a contact hole can be disposed in the first planarization layer 115a, and the third connection line CL3 extending in the first direction D1 and the fifth connection line CL5 extending in the second direction D2 intersecting the first direction D1 can be electrically connected through the contact hole. Therefore, at the center of the optical area OA, the fifth connection line CL5 can be electrically connected to the third connection line CL3 and electrically connected to the first direct current power lines DCL1 through the third connection line CL3. Also, at the center of the optical area OA, the connection between the fourth connection line CL4 and the sixth connection line CL6 can also be identical to the connection between the third connection line CL3 and the fifth connection line CL5.

In general, like the normal area, the lines of the subpixels are disposed and extend in the optical area in which the electronic optical device is disposed. However, there is a problem in that the recognition performance of the electronic optical device deteriorates as an open ratio of the optical area decreases.

Therefore, in the display device 100 according to the embodiment of the present specification, at the boundary between the optical area OA and the normal area NA, the first connection line CL1 and the second connection line CL2 intersecting the first direct current power lines DCL1 and the second direct current power lines DCL2 can be disposed, the first connection line CL1 can electrically connect the first direct current power lines DCL1, and the second connection line CL2 can electrically connect the second direct current power lines DCL2. Therefore, in the optical area OA, only the third connection line CL3 electrically connected to the first connection line CL1 and the fourth connection line CL4 electrically connected to the second connection line CL2 extend in the first direction D1. That is, the number of lines applied in the first direction D1 in the optical area OA can be reduced, which can increase the open ratio of the optical area OA. Therefore, the recognition performance of the electronic optical device 170 in the optical area OA can be improved.

In addition, the number of lines extending in the first direction D1 in the optical area OA can be reduced, such that the overlap between the lines disposed in the optical area OA can be minimized, which can minimize the occurrence of parasitic capacitance. In addition, the occurrence of parasitic capacitance can be minimized, which can suppress in advance a defect such as crosstalk or Mura.

In addition, a material with low resistance can be used for the third connection line CL3, the fourth connection line CL4, the fifth connection line CL5, and the sixth connection line CL6 that apply the direct current power in the optical area OA, such that the RC load can be reduced, and a defect such as crosstalk or Mura in the optical area OA can be suppressed.

The exemplary embodiments of the present disclosure can also be described as follows:

According to an aspect of the present disclosure, a display device comprising a substrate comprising a display area comprising an optical area and a normal area and comprising a plurality of subpixels, a plurality of subpixel circuits disposed in the plurality of subpixels, a plurality of first direct current power lines and a plurality of second direct current power lines extending in a first direction in the normal area and electrically connected to the subpixel circuit disposed in the normal area among the plurality of subpixel circuits, a first connection line extending in a second direction intersecting the first direction at a boundary between the optical area and the normal area and configured to electrically connect the plurality of first direct current power lines, a second connection line extending in the second direction at the boundary between the optical area and the normal area and configured to electrically connect the plurality of second direct current power lines, a third connection line extending in the first direction in the optical area, electrically connected to the first connection line, and electrically connected to the subpixel circuit disposed in the optical area among the plurality of subpixel circuits, and a fourth connection line extending in the first direction in the optical area, electrically connected to the second connection line, and electrically connected to the subpixel circuit disposed in the optical area among the plurality of subpixel circuits.

The third connection line and the fourth connection line can extend while traversing a center of the optical area. The display device can further comprise a plurality of fifth connection lines branching off from the third connection line in the second direction in the optical area, and a plurality of sixth connection lines branching off from the fourth connection line in the second direction in the optical area.

The display device can further comprise a plurality of transistors disposed on the substrate in the normal area, a first planarization layer configured to planarize upper portions of the plurality of transistors, an auxiliary electrode disposed on the first planarization layer, a second planarization layer disposed on the first planarization layer and the auxiliary electrode, and a plurality of light-emitting elements disposed on the second planarization layer, electrically connected to the plurality of transistors by the auxiliary electrode, and each comprising an anode, an organic layer, and a cathode, the third connection line and the fourth connection line can be positioned on the same layer as source electrodes and drain electrodes of the plurality of transistors.

The fifth connection line and the sixth connection line can be positioned on the same layer as the auxiliary electrode. The plurality of first direct current power lines and the plurality of second direct current power lines can be each any one of a first initialization voltage line, a second initialization voltage line, and a bias voltage line. The display device can further comprise an electronic optical device disposed below the substrate in the optical area.

According to another aspect of the present disclosure, a display device comprising a substrate comprising a display area comprising an optical area and a normal area and comprising a subpixels, a plurality of subpixel circuits disposed in the subpixels, a plurality of first direct current power lines and a plurality of second direct current power lines extending in a first direction in the normal area and electrically connected to the subpixel circuit disposed in the normal area among the plurality of subpixel circuits, a first connection line extending in a second direction intersecting the first direction at a boundary between the optical area and the normal area and configured to electrically connect the plurality of first direct current power lines, a second connection line extending in the second direction at the boundary between the optical area and the normal area and configured to electrically connect the plurality of second direct current power lines, a third connection line extending in the first direction in the optical area, electrically connected to the first connection line, and electrically connected to the subpixel circuit disposed in the optical area among the plurality of subpixel circuits, and a fourth connection line extending in the first direction in the optical area, electrically connected to the second connection line, and electrically connected to the subpixel circuit disposed in the optical area among the plurality of subpixel circuits, the number of first direct current power lines and second direct current power lines disposed in the normal area is larger than the number of third connection line and fourth connection line disposed in the optical area.

The third connection line and the fourth connection line are each provided as one connection line, and the third connection line and the fourth connection line can extend while traversing a center of the optical area. The display device can further comprise a plurality of fifth connection lines branching off from the third connection line in the second direction in the optical area, and a plurality of sixth connection lines branching off from the fourth connection line in the second direction in the optical area.

The display device can further comprise a plurality of transistors disposed on the substrate in the normal area, a first planarization layer configured to planarize upper portions of the plurality of transistors, an auxiliary electrode disposed on the first planarization layer, a second planarization layer disposed on the first planarization layer and the auxiliary electrode, and a plurality of light-emitting elements disposed on the second planarization layer, electrically connected to the plurality of transistors by the auxiliary electrode, and each comprising an anode, an organic layer, and a cathode, the third connection line and the fourth connection line can be positioned on the same layer as source electrodes and drain electrodes of the plurality of transistors.

The fifth connection line and the sixth connection line can be positioned on the same layer as the auxiliary electrode. The plurality of first direct current power lines and the plurality of second direct current power lines can be each any one of a first initialization voltage line, a second initialization voltage line, and a bias voltage line.

Although the exemplary embodiments of the present disclosure have been described in detail with reference to the accompanying drawings, the present disclosure is not limited thereto and can be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display device comprising:
a display including a plurality of subpixels on a substrate, wherein the display includes an optical area overlapping an electronic optical device disposed below the substrate and includes a display area outside the optical area;
a plurality of subpixel circuits disposed in the plurality of subpixels;
a plurality of first direct current power lines extending in a first direction in the display area and electrically connected to corresponding first subpixel circuits disposed in the display area among the plurality of subpixel circuits;
a plurality of second direct current power lines extending in the first direction in the display area and spaced apart from the first direct current power lines and electrically connected to corresponding second subpixel circuits disposed in the display area among the plurality of subpixel circuits;
a first connection line extending in a second direction intersecting the first direction at a boundary between the optical area and the normal area and configured to electrically connect the first direct current power lines;
a second connection line extending in the second direction at the boundary between the optical area and the display area and spaced apart from the first connection line and configured to electrically connect the plurality of second direct current power lines;
a third connection line extending in the first direction across the optical area, electrically connected to the first connection line, and electrically connected to corresponding third subpixel circuits disposed in the optical area among the plurality of subpixel circuits; and
a fourth connection line extending in the first direction in the optical area and spaced apart from the third connection line, electrically connected to the second connection line, and electrically connected to fourth corresponding subpixel circuits disposed in the optical area among the plurality of subpixel circuits.

2. The display device of claim 1, wherein the third connection line and the fourth connection line extend while traversing a center of the optical area.

3. The display device of claim 2, further comprising:
a plurality of fifth connection lines branching off from the third connection line in the second direction in the optical area; and
a plurality of sixth connection lines branching off from the fourth connection line in the second direction in the optical area.

4. The display device of claim 3, further comprising:
a plurality of transistors disposed on the substrate in the display area;
a first planarization layer planarizing upper portions of the plurality of transistors;
an auxiliary electrode disposed on the first planarization layer;
a second planarization layer disposed on the first planarization layer and the auxiliary electrode; and
a plurality of light-emitting elements disposed on the second planarization layer, electrically connected to the plurality of transistors by the auxiliary electrode, and each comprising an anode, an organic layer, and a cathode,
wherein the third connection line and the fourth connection line are positioned on a same layer as source electrodes and drain electrodes of the plurality of transistors.

5. The display device of claim 4, wherein the fifth connection line and the sixth connection line are positioned on a same layer as the auxiliary electrode.

6. The display device of claim 1, wherein each of the first direct current power lines and the second direct current power lines include any one of a first initialization voltage line, a second initialization voltage line, and a bias voltage line.

7. The display device of claim 1, wherein a single third connection line and a single fourth connection line cross the optical area.

8. The display device of claim 1, wherein a number of first direct current power lines and second direct current power lines disposed in the display area is larger than a number of the third connection line and fourth connection line disposed in the optical area.

9. The display device of claim 1, wherein the third connection line and the fourth connection line extend as one connection line while traversing a center of the optical area.

10. The display device of claim 9, further comprising:
a plurality of fifth connection lines branching off from the third connection line in the second direction in the optical area; and
a plurality of sixth connection lines branching off from the fourth connection line in the second direction in the optical area,
wherein a spacing between adjacent fifth connection lines is greater than a spacing between adjacent fifth and sixth connection lines.

11. The display device of claim 1, further comprising:
a plurality of fifth connection lines branching off from the third connection line in the second direction in the optical area; and
a plurality of sixth connection lines branching off from the fourth connection line in the second direction in the optical area,
wherein the fifth connection line and the sixth connection line only extend only in the optical area.

12. The display device of claim 11, wherein the fifth connection line and the sixth connection line extend across the entire optical area.

13. The display device of claim 1, wherein the first connection line and the second connection line extend into a non-display area of the display device.
